(19) United States
(12) Patent Application Publication
(10) Pub. No.: US 2026/0090179 A1
(43) Pub. Date: Mar. 26, 2026

(54) LEAD-FREE DOUBLE PEROVSKITE SHORT-WAVE INFRARED PHOTODETECTORS AND PROCESSES FOR FORMING

(71) Applicants: Honda Motor Co., Ltd., Tokyo (JP); Utah State University, Logan, UT (US)

(72) Inventors: Gugang CHEN, Palo Alto, CA (US); Yi RAO, Logan, UT (US)

(21) Appl. No.: 18/898,271

(22) Filed: Sep. 26, 2024

(51) Int. Cl. H10K 30/40; H10K 30/86; H10K 71/40; H10K 85/50

(52) U.S. Cl. CPC H10K 30/40; H10K 30/86; H10K 71/441; H10K 85/50

(57) ABSTRACT

Aspects of the present disclosure generally relate to a new class of compositions utilized for detecting short-wave infrared (SWIR) light, to devices including the compositions, and to photodetectors including the compositions. Aspects of the present disclosure also generally relate to processes for forming the compositions, the devices, and the photodetectors. In an aspect, a process for forming a SWIR device is provided. The process includes forming a precursor solution comprising: a first compound (AX), a second compound (BX), a third compound (CX₃), a nitrogen-containing compound, and a solvent. The process further includes: dispersing the precursor solution on a substrate surface of a substrate and annealing the dispersed precursor solution on the substrate at an annealing temperature that is from about 100° C. to about 300° C. to form a film composition comprising: the nitrogen-containing compound or ion thereof; and a lead-free double perovskite represented by Formula (I): A₂BCX₆ (I).

### FIELD

Aspects of the present disclosure generally relate to a new class of compositions utilized for detecting short-wave infrared (SWIR) light, to devices including the compositions, and to photodetectors including the compositions. Aspects of the present disclosure also generally relate to processes for forming the compositions, the devices, and the photodetectors.

### BACKGROUND

SWIR light is finding widespread use in both civilian and military contexts, including inspection processes, nighttime imaging, and machine vision due to the unique capability to produce high-resolution and high-contrast imaging. As such, there is increasing demand for practical and effective SWIR detectors. Conventional technologies have attempted to increase the detector's response in the SWIR region for certain materials such as organics, quantum dots, 2-D materials, and perovskites. However, conventional SWIR materials have several limitations including high cost, potential harm to the environment, difficult and complex fabrication, and relatively low performance results.

There is a need for new compositions for detecting SWIR light, devices for detecting SWIR light, and to photodetectors for detecting SWIR light. There is also a need for new processes for forming such compositions, devices, and photodetectors.

### SUMMARY

Aspects of the present disclosure generally relate to a new class of compositions utilized for detecting SWIR light, to devices including the compositions, and to photodetectors including the compositions. Aspects of the present disclosure also generally relate to processes for forming the compositions, the devices, and the photodetectors.

Unlike conventional SWIR photodetectors, SWIR photodetectors of the present disclosure may be characterized as having high responsivity and/or high specific detectivity under ambient conditions (for example, at room temperature). Moreover, compositions and photodetectors described herein have improved chemical stability and long-term stability over conventional technologies. Improved processes for forming the compositions and photodetectors are also described herein. For example, the inventors found a scalable and efficient solution-based fabrication process for fabricating, e.g., a thin film of the composition and fabricating devices such as photodetectors that include the composition. Traditional methods for making SWIR compositions and photodetectors, in contrast, are expensive.

Compositions of the present disclosure have unique light absorbance wavelengths from, for example, the visible to SWIR bands. Compositions described herein may be incorporated into devices for detecting, sensing, localizing, and/or imaging various objects by SWIR light or radiation. Aspects described herein may find applications in, for example, automobiles, remote sensing, vehicle control, automated inspection, identifying and sorting, surveillance, anti-counterfeiting, and environmental chemical analysis, among other applications.

In an illustrative, but non-limiting, example, the inventors found a composition that includes a lead-free (Pb-free) double perovskite (Cs₂AgBiBr₆) and hydrazinium iodide that enables detection in the SWIR range. This example, and other aspects described herein, show excellent photovoltaic capabilities—for example, high responsivity, high specific detectivity, and high sensitivity—at room temperature and under ambient conditions. The compositions and devices incorporated the compositions are relatively cheap, and less complex, to manufacture relative to conventional technologies and the components of the composition are nontoxic. That is, aspects described herein are distinguished from conventional technologies in the field of SWIR photodetection.

In an aspect, a process for forming a short-wave infrared device is provided. The process includes forming a precursor solution comprising: a first compound (AX) comprising a first monovalent metal cation (A) and a first monovalent anion (X); a second compound (BX) comprising a second monovalent metal cation (B) and a second monovalent anion (X), the second monovalent metal cation being different from the first monovalent metal cation; a third compound (CX₃) comprising a trivalent metal cation (C) and three third monovalent anions (X), each X being the same or different; a nitrogen-containing compound; and a solvent. The process further includes dispersing the precursor solution on a substrate surface of a substrate. The process further includes annealing the dispersed precursor solution on the substrate by heating the substrate at an annealing temperature that is from about 100° C. to about 300° C. to form a film composition comprising: the nitrogen-containing compound or ion thereof; and a lead-free double perovskite represented by Formula (I): A₂BCX₆ (I).

In another aspect, a process for forming a short-wave infrared device is provided. The process includes forming a precursor solution comprising: a first compound (AX) comprising a first monovalent metal cation (A) and a first monovalent anion (X); a second compound (BX) comprising a second monovalent metal cation (B) and a second monovalent anion (X), the second monovalent metal cation being different from the first monovalent metal cation; a third compound (CX₃) comprising a trivalent metal cation (C) and three third monovalent anions (X), each X being the same or different; a nitrogen-containing compound or ion thereof comprising hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof; and a solvent comprising dimethylformamide, dimethylsulfoxide, gamma-butyrolactone, tetrahydrofuran, or combinations thereof. The process further includes dispersing the precursor solution on a substrate. The process further includes annealing the dispersed precursor solution on the substrate by heating the substrate at an annealing temperature that is from about 100° C. to about 300° C. to form a film composition comprising: the nitrogen-containing compound or ion thereof; and a lead-free double perovskite represented by Formula (I): A₂BCX₆ (I).

In another aspect, short-wave infrared device is provide. The short-wave infrared device includes a hole transport layer. The short-wave infrared device further includes a film disposed on the hole transport layer, the film comprising a composition comprising: a nitrogen-containing compound or ion thereof; and a lead-free double perovskite represented by Formula (I):

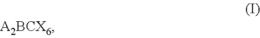

wherein: A of Formula (I) is a first monovalent metal or cation thereof; B of Formula (I) is a second monovalent metal or cation thereof, the second monovalent metal being different from the first monovalent metal; C of Formula (I) is a trivalent metal or cation thereof; and each X of Formula (I) is, independently, a halogen or ion thereof, each X being the same or different.

### BRIEF DESCRIPTION OF THE DRAWINGS

So that the manner in which the above recited features of the present disclosure may be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, for the disclosure may admit to other equally effective aspects.

FIG. 1 is a schematic of a device fabrication process.

FIG. 2 is an energy level diagram associated with each component of a Cs₂AgBiBr₆-containing device, with the lower number representing the valence band and the upper value representing the conductance band.

FIG. 3 shows responsivity curves of the example Cs₂AgBiBr₆-containing device as a function of voltage at various illumination power levels.

FIG. 4 shows responsivity versus power of the example Cs₂AgBiBr₆-containing device at various voltage levels.

FIG. 5 shows current versus time data of the example Cs₂AgBiBr₆-containing device at various illumination power densities.

### DETAILED DESCRIPTION

Aspects of the present disclosure generally relate to a new class of compositions utilized for detecting SWIR light, to devices including the compositions, and to photodetectors including the compositions. As used herein, a “composition” may include component(s) of the composition, reaction product(s) of two or more components of the composition, and/or a remainder balance of remaining starting component(s), or combinations thereof. Aspects of the present disclosure also generally relate to processes for forming the compositions, the devices, and the photodetectors.

SWIR light, spanning wavelengths from about 700 nanometers and 2,500 nanometers, has become important in many applications. SWIR light has found myriad uses in imaging, remote sensing, communications, electronics, spectroscopy, security, and many hyperspectral imaging processes. SWIR imaging is able to penetrate harsh weather conditions such as fog better than visible light. Additionally, machine vision in the SWIR range is important in military applications for the discrimination of camouflaged materials and even the detection of landmines and chemical warfare agents. As such, practical, affordable, and sensitive SWIR photodetectors are needed.

Conventional approaches to SWIR photodetection have relied heavily on narrow bandgap semiconductors and quantum structures. However, such conventional approaches come with their own set of limitations. For example, their fabrication is often convoluted and expensive making them not suitable for commercial use. Moreover, organic-based and quantum dot-based detectors have seen investigated, yet their SWIR responses are not matched to their inorganic counterparts. Certain alternative solutions, while demonstrating high SWIR responsivity, involve intricate or high-temperature fabrication processes, constraining their widespread use. Additionally, while two-dimensional graphene-based materials have shown promise, their practical application has been limited due to low light absorption, short carrier lifetimes, and the need for expensive additives. Lead-based semiconductors have been proven easy and cheap to manufacture such as PbS⁸ and PbSe⁹, but may be toxic. Thus, the development of a new device is needed to overcome the aforementioned shortcomings while still providing good responsivity in the SWIR region.

Hybrid organic-inorganic lead halide perovskites are low-cost materials for photovoltaic devices and have efficiencies of over 22%. While organic-inorganic lead halide perovskite devices have good photophysical properties, they are unable to be successful commercially due to their instability and possible toxicity. This instability arises due to the photo-induced degradation or field-induced degradation that occurs in the device because of the migration of halide ions and ion vacancies. This ion migration leads to instability in optoelectronic devices. A recent approach towards lead-free perovskite materials is the substitution of Pb²⁺ by heterovalent M³⁺ cations. Specifically, bismuth shows a lot of promise as a replacement and is not toxic. However, the typical perovskite structure (A¹⁺M²⁺X₃) cannot be used with Bi³⁺ due to its higher charge.

Thus, there is a need for new compositions that have a decreased bandgap and increased usefulness in the SWIR regime. To overcome, at least, the aforementioned shortcomings, the inventors found various compositions that may be utilized for photodetection in the SWIR range. In some examples, compositions utilized for photodetection in the SWIR range may include a Pb-free double perovskite and a nitrogen-containing compound. The inventors also developed a coating process to form effective SWIR photodetectors with the double perovskite-containing composition using a fluoride-doped tin oxide-glass device as a substrate and poly(3,4-ethylenedioxythiophene) polystyrene sulfonate as a hole transport layer. The device achieved unexpectedly high characteristics including responsivity, external quantum efficiency, specific detectivity, and sensitivity at room temperature and under ambient conditions. Room temperature is from about 15° C. to about 25° C. Ambient conditions refer to conditions at about 50% relative humidity and a pressure of about 1 atmosphere.

Aspects of the present disclosure generally relate to processes for forming compositions that include a Pb-free double perovskite and a nitrogen-containing compound. Such compositions may be utilized as a SWIR material. The compositions may be in the form of a film such as a thin film. In some aspects, the composition may be utilized in a process to form a SWIR device such as a SWIR photodetector. In some aspects, processes for forming a SWIR device includes forming a precursor solution that includes metal compounds, adding an additive (e.g., a nitrogen-containing compound) to the precursor solution, dispersing the resultant precursor solution on a substrate, and annealing the dispersed precursor solution on the substrate.

The Pb-free double perovskite of the composition may be represented by Formula (I):

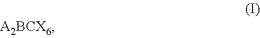

wherein:
A of Formula (I) is a first monovalent metal or cation thereof;
B of Formula (I) is a second monovalent metal or cation thereof that is different from the first monovalent metal cation;
C of Formula (I) is a trivalent metal or cation thereof;
each X of Formula (I) is, independently, a monovalent element or anion thereof, each X of Formula (I) being the same or different; and
A and B are different.

Double perovskites belong to a class of materials called elapsolites and provide an expansion to the conventional perovskite system. Double perovskites feature a highly symmetric cubic double with the formula A₂B¹⁺C³⁺X₆.

A process for forming a composition may include forming a mixture comprising: a first compound AX (or A⁺X⁻) that includes a monovalent metal A (or A⁺) and a first monovalent anion X (or X⁻); a second compound BX comprising a second monovalent metal B (or B⁺) and a second monovalent anion X (or X⁻); a third compound CX₃ (or C³⁺ (X⁻)₃) that includes a trivalent metal C (or C³⁺) and three third monovalent anions X (or X⁻); and a nitrogen-containing compound.

AX and BX are different compounds. Each X (or X⁻) may be the same or different. For example the X of AX may be the same or different from the X of BX and/or one or more X's of CX₃. Additionally, or alternatively, each X of CX₃ may be the same or different. The first compound, the second compound, and/or the third compound may include metal salts.

The first monovalent metal A (or cation A⁺) of the first compound AX may include an alkali metal, such as cesium (Cs), rubidium (Rb), potassium (K), sodium (Na), lithium (Li), and/or cation thereof. The first monovalent anion X (or X⁻) of the first compound may include a halogen (or ion thereof) such as fluorine (F), chlorine (Cl), bromine (Br), or iodine (I), such as Br, I, or Cl, such as Br or Cl. Examples of first compounds may include, but are not limited to, CsBr, CsI, CsCl, RbBr, RbI, RbCl, KBr, KI, KCl, NaBr, NaI, NaCl, LiBr, LiI, LiCl, or combinations thereof.

The second monovalent metal B (or cation B⁺) of the second compound BX may include a transition metal (such as silver (Ag), gold (Au), copper (Cu)), an alkali metal (such as Na or K), a cation thereof, or combinations thereof, such as Ag, Na, K, or a cation thereof. The second monovalent anion X (or X⁻) of the second compound may include a halogen (or ion thereof) such as fluorine (F), chlorine (Cl), bromine (Br), or iodine (I), such as Cl, Br, or I, such as Br or Cl. Examples of second compounds may include, but are not limited to, AgBr, AgI, AgCl, CuBr, CuI, CuCl, AuBr, AuI, AuCl, NaBr, NaI, NaCl, KBr, KI, KCl, or combinations thereof.

The trivalent metal C (or cation C³⁺) of the third compound CX₃ may include bismuth (Bi), antimony (Sb), or indium (In), or cation thereof, such as Bi, Sb, and/or cation thereof. The three third monovalent anions X (or X⁻) of the second compound may include a halogen (or ion thereof) such as fluorine (F), chlorine (Cl), bromine (Br), or iodine (I), such as Cl, Br, or I, such as Br or Cl. Examples of second compounds may include, but are not limited to, BiBr₃, BiI₃, BiCl₃, SbBr₃, SbI₃, SbCl₃, InBr₃, InI₃, InCl₃, or combinations thereof, such as BiBr₃, SbBr₃, InCl₃, or combinations thereof, such as BiBr₃, SbBr₃, or combinations thereof.

In some embodiments, the Pb-free double perovskite of Formula (I) may be represented by Formula (II):

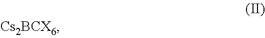

Cs of Formula (II) is cesium and/or ion thereof. B of Formula (II) may include Ag, Cu, Au, Na, K, and/or ion thereof, such as Ag, Cu, Na, and/or ion thereof. C of Formula (II) may include Bi, Sb, In, and/or ion thereof, such as Bi, Sb, and/or ion thereof. Each X of Formula (II) may be, independently, a halogen such as F, Cl, Br, I, or combinations thereof, such as Br, I, Cl, or combinations thereof, such as Br, Cl, or combinations thereof. Each X of Formula (II) being the same or different.

Illustrative, but non-limiting, examples of Pb-free double perovskite (represented by Formula (I) or Formula (II)) that may be formed by processes described herein may include Cs₂AgBiBr₆, Cs₂AgSbBr₆, Cs₂AgInCl₆, Cs₂CuBiBr₆, and Cs₂NaBiCl₆, among many others.

Any suitable nitrogen-containing compound or ion thereof may be utilized. Illustrative, but non-limiting, examples of nitrogen-containing compounds may include hydrazine, ammonia, methylamine, dimethylamine, trimethylamine, ethylamine, diethylamine, triethylamine, triisopropylamine, aziridine, diaziridine, formamidine, amidine, guanidine, or combinations thereof. Illustrative, but non-limiting, examples of ions of nitrogen-containing compounds may include hydrazinium, ammonium, methylammonium, dimethylammonium, trimethylammonium, ethylammonium, diethylammonium, triethylammonium, triisopropylammonium, aziridinium, diaziridinium, formamidinium, amidinium, guanidinium, or combinations thereof. Nitrogen-containing compounds may include salts, such as halide salts, of such ions. An illustrative, but non-limiting, example of a nitrogen-containing compounds may include hydrazinium iodide, ([NH₂NH₃⁺I⁻], HAI).

The nitrogen-containing compound may include a protonated nitrogen atom (such as a nitrogen atom with a formal charge of +1) such that the nitrogen-containing compound comprises a cationic group. The nitrogen-containing compound may optionally include any suitable counter anion such as a halogen, such as Cl, Br, or I, such as I or Br. The nitrogen-containing compound may be made by protonating a nitrogen-containing compound with an acid or other material, such as hydrochloric acid (HCl), hydrobromic acid (HBr), hydroiodic acid (HI), or combinations thereof. A non-limiting example of a suitable nitrogen-containing compound may include hydrazinium iodide (NH₂NH₃I).

Aspects of the present disclosure also relate to processes for forming a SWIR device. The process for forming a SWIR device may include forming a precursor solution that includes: (a) a first compound (AX) comprising a first monovalent metal (A) and a first monovalent anion (X); (b) a second compound (BX) comprising a second divalent metal (B) and a second monovalent anion (X); (c) a third compound (CX₃) that includes a trivalent metal (C) and three third monovalent anions (X), each X of the first, second, and third compounds may be the same or different; (d) a nitrogen-containing compound; and (e) a solvent.

Non-limiting examples of the first compound, the second compound, the third compound, and the nitrogen-containing compound (or ion thereof) are described above.

Any suitable solvent, or solvent mixture, may be utilized for the precursor solution. Non-limiting examples of suitable solvents may include organic solvents such as, dimethylformamide, dimethylsulfoxide, gamma-butyrolactone, tetrahydrofuran, or combinations thereof. The solvent or solvent mixture may be anhydrous.

In at least one aspect, a solvent mixture is utilized for the precursor solution. For example, a solvent mixture comprising a first solvent and a second solvent may be utilized. A volume ratio of the first solvent to the second solvent may be from about 1:1 to about 17:1, such as from about 2:1 to about 16:1, such as from about 3:1 to about 15:1, 4:1 to about 14:1, such as from about 5:1 to about 13:1, such as from about 6:1 to about 12:1, such as from about 7:1 to about 11:1, such as from about 8:1 to about 10:1, such as about 9:1.

In a non-limiting example, the first solvent may be dimethylsulfoxide and second solvent may be gamma-butyrolactone, and a volume ratio of the dimethylsulfoxide:gamma-butyrolactone may be about 9:1.

The precursor solution may include an amount of the first compound (AX) in the solvent that is from about 0.2 M to about 2.2 M, such as from about 0.4 M to about 2 M, such as from about 0.6 M to about 1.8 M, such as from about 0.8 M to about 1.6 M, such as from about 1 M to about 1.4 M, such as about 1.2 M.

The precursor solution may include an amount of the nitrogen-containing compound in the solvent that is from about 0.2 M to about 2.2 M, such as from about 0.4 M to about 2 M, such as from about 0.6 M to about 1.8 M, such as from about 0.8 M to about 1.6 M, such as from about 1 M to about 1.4 M, such as about 1.2 M.

The precursor solution may include an amount of the second compound (BX) in the solvent that is from 0.1 M to about 1.1 M, such as from about 0.2 M to about 1 M, such as from about 0.3 M to about 0.9 M, such as from about 0.4 M to about 0.8 M, such as from about 0.5 M to about 0.7 M, such as about 0.6 M.

The precursor solution may include an amount of the third compound (CX₃) in the solvent that is from 0.1 M to about 1.1 M, such as from about 0.2 M to about 1 M, such as from about 0.3 M to about 0.9 M, such as from about 0.4 M to about 0.8 M, such as from about 0.5 M to about 0.7 M, such as about 0.6 M.

A molar ratio of the first compound (AX) to the nitrogen-containing compound (e.g., HAI) in the precursor solution may be from about 10:1 to about 2:1, such as from about 9:1 to about 3:1, such as from about 8:1 to about 4:1, such as from about 7:1 to about 5:1.

A molar ratio of the first compound (AX) plus the nitrogen-containing compound (e.g., HAI) to the second compound (BX) in the precursor solution may be from about 10:1 to about 0.5:1, such as from about 5:1 to about 1:1, such as from about 3:1 to about 1.5:1, such as from about 2.5:1 to about 1.8:1, such as about 2:1. For example, a molar ratio of the CsBr+HAI to AgBr in the precursor solution may be about 2:1.

A molar ratio of the first compound (AX) plus the nitrogen-containing compound (e.g., HAI) to the third compound (CX₃) in the precursor solution may be from about 10:1 to about 0.5:1, such as from about 5:1 to about 1:1, such as from about 3:1 to about 1.5:1, such as from about 2.5:1 to about 1.8:1, such as about 2:1. For example, a molar ratio of the CsBr+HAI to BiBr₃ in the precursor solution may be about 2:1.

A molar ratio of the first compound (AX) to the second compound (BX) in the precursor solution may be from about 0.5:1 to about 4:1, such as from about 1:1 to about 3:1, such as about 2:1.

A molar ratio of the first compound (AX) to the third compound (CX₃) in the precursor solution may be from about 0.5:1 to about 4:1, such as from about 1:1 to about 3:1, such as about 2:1.

A molar ratio of the second compound (BX) to the third compound (CX₃) in the precursor solution may be from about 0.3:1 to about 4:1, such as from about 0.5:1 to about 3:1, such as from about 0.75:1 to about 2:1, such as about 1:1.

The precursor solution may include a molar ratio of the Pb-free double perovskite to the nitrogen-containing compound that is from about 0.1:1 to about 0.4:1, such as from about 0.12:1 to about 0.3:1, such as from about 0.14:1 to about 0.22:1, such as about 0.16:1.

The process for forming the SWIR device may further include dispersing the precursor solution onto a substrate and/or a hole transport layer (HTL). In the description for processes for forming a SWIR device (e.g., a SWIR photodetector), reference to substrate includes reference to both substrate and HTL unless specified to the contrary or the context clearly indicates otherwise. For example, dispersing the precursor solution onto the substrate refers to dispersing the precursor solution onto the substrate and/or onto the HTL (if present).

Any suitable substrate may be utilized such as glass, sapphire, polymer, or fluorine-doped tin oxide (FTO)-coated glass. The substrate may be a flexible material or an inflexible material. For example, glass, sapphire, FTO-coated glass, or a flexible polymer may be utilized as the substrate. The HTL may be made of, or include, any suitable material such as poly(3,4-ethylenedioxythiophene) polystyrene sulfonate (PEDOT:PSS).

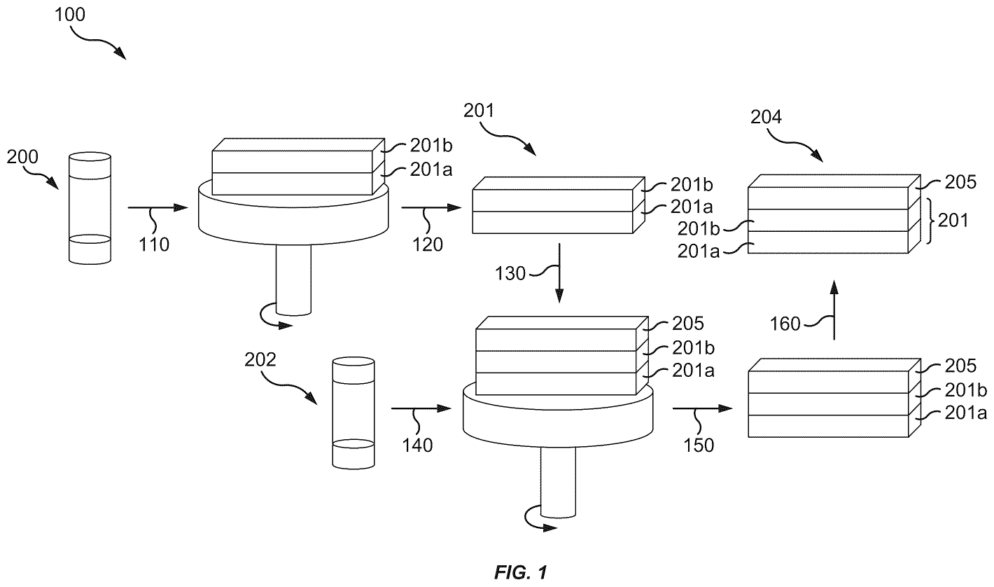

An aspect of the formed device is shown in FIG. 1, further described below. As shown, the example device 204 includes a substrate 201. The substrate 201 may include a first layer 201a (for example, FTO-coated glass) and a second layer 201b (for example, HTL) disposed over at least a portion of the first layer 201a. The precursor solution 202 is dispersed onto the HTL (e.g., the second layer 201b) such that a thin film of the composition (e.g., the double perovskite-containing layer 205) forms on the HTL. The double perovskite-containing layer 205 includes the Pb-free double perovskite and the nitrogen-containing compound.

During the dispersing the precursor solution 202 onto the substrate, the substrate may be kept at about room temperature (e.g., from about 15° C. to about 25° C.).

The precursor solution 202 may be dispersed onto the substrate 201 by any suitable means to form a thin film of precursor solution on the substrate. A non-limiting example of dispersing is chemical solution deposition. In general, chemical solution deposition is a process for depositing thin films on a substrate surface by chemical reaction or electrochemical reaction to form a film. Chemical solution deposition may be utilized to accurately control the stoichiometric ratio and provide a film with good uniformity. A non-limiting example of chemical solution deposition that may be utilized includes spin coating. Spin coating includes spinning (or rotating) the substrate at a suitable speed and dispersing the precursor solution onto the rotating substrate. For example, the precursor solution may form a thin film on a rotating substrate.

The substrate may be rotated at a suitable speed to disperse the precursor solution (and form a thin film of precursor solution) but not at such an excessive speed to dislodge the precursor solution from the substrate. Suitable rotation speeds may include 100 revolutions per minute (rpm) or more, 4,000 rpm or less, or combinations thereof, such as from about 500 rpm to about 3,500 rpm, such as about 1,000 rpm to about 3,000 rpm, such as from about 1,500 rpm to about 2,500 rpm, such as about 2,000 rpm.

The substrate may be rotated at a suitable angular acceleration that is about 50 radians per second squared (rad/s²), about 1,000 rad/s² or less, or combinations thereof, such as from about 50 rad/s² to about 1,000 rad/s², such as from about 100 rad/s² to about 900 rad/s², such as from about 200 rad/s² to about 800 rad/s², such as from about 300 rad/s² to about 700 rad/s², such as from about 400 rad/s² to about 600 rad/s², such as about 500 rad/s².

The precursor solution may be dispersed onto the substrate for a period of about 1 second or more, about 20 minutes or less, or combinations thereof, such as from about 1 second to about 20 minutes, such as from about 5 seconds to about 10 minutes, such as from about 10 seconds to about 5 minutes, such as from about 20 seconds to about 5 minutes, such as from about 30 seconds to about 1 minute, such as about 50 seconds, or from about 5 seconds to about 90 seconds, such as from about 25 seconds to about 75 seconds, such as about 50 seconds.

Optionally, spin coating may be performed in a glove box, under a non-reactive gas (such as N₂ or Ar), or combinations thereof.

Prior to dispersing the precursor solution onto the substrate, the precursor solution may be optionally pre-heated. The precursor solution comprising the first compound, second compound, third compound, nitrogen-containing compound, and solvent may be optionally pre-heated at a precursor solution pre-heating temperature that is from about 40° C. to about 110° C., such as from about 50° C. to about 100° C., such as from about 60° C. to about 90° C., such as from about 70° C. to about 80° C., such as about 75° C.

Pre-heating of the precursor solution prior to dispersing the precursor solution on the substrate may affect the crystallization rate of the composition. For example, pre-heating the precursor solution may cause the solvent in the precursor solution to evaporate more quickly, which may increase the nucleation density and increase crystal perovskite strength, resulting in better film quality. This better film quality may have higher light absorption efficiency, and when the film is in a device, the current of the device may be increased. Additionally, the pre-heating of the precursor solution may advantageously affect the photoelectric performance, such as specific detectivity and responsivity, of the resulting device.

Under the spin-coating process, and as described above, appropriate pre-heating temperatures may promote crystallization and the formation of a uniform film with good photoelectric performance. In addition, the inventors found that various conditions of the spin coating process may have a significant impact on the resulting performance characteristics such as responsivity and specific detectivity of the resulting device, e.g., photodetector. For example, higher or lower annealing temperatures may reduce performance characteristics. As another example, faster or slower rotation of the substrate during spin coating may reduce responsivity and specific detectivity.

The process for forming the SWIR device may further include annealing the dispersed solution upon the substrate. A purpose of the annealing may include forming a pure-phase substance, eliminating excess material. The pure-phase substance may also promote continuous growth of grains and an increase in size, further improving the stability of the film. In some aspects, a thin film of precursor solution is annealed on the substrate. According to some aspects, depending on the annealing conditions, and for example, the chemical composition of the precursor solution, the wavelength of maximum SWIR absorbance of the resulting composition comprising the perovskite may change. Annealing may optionally be performed under vacuum conditions.

Annealing of the dispersed precursor solution may be performed at an annealing temperature that is from about 100° C. to about 250° C., such as from about 120° C. to about 220° C., such as from about 130° C. to about 210° C., such as from about 140° C. to about 200° C., such as from about 150° C. to about 190° C., such as from about 160° C. to about 180° C., such as about 170° C. Annealing of the dispersed precursor solution may be performed for any suitable period. Non-limiting examples of annealing times are from about 1 minute to about 60 minutes, such as from about 10 minutes to about 50 minutes, such as from about 20 minutes to about 40 minutes, such as about 30 minutes.

The annealing forms a composition that includes the Pb-free double perovskite represented by Formula (I) or Formula (II) and a nitrogen-containing compound. This composition, which may be in the form of a film, may be utilized as a SWIR material.

In some aspects, the substrate used for the process for forming the SWIR device may be formed by any suitable substrate-forming process or may be obtained commercially. The substrate-forming process may include: (a) cleaning an FTO-coated glass (e.g., the first layer 201a); and (b) depositing a conductive layer comprising a conductive polymer such as poly(3,4-ethylenedioxythiophene) polystyrene sulfonate (PEDOT:PSS) on the FTO-coated glass to form the substrate 201. The PEDOT:PSS is the HTL (e.g., the second layer 201b) of the substrate.

The cleaning process of operation (a) of the substrate-forming process may include immersing the FTO-coated glass in any suitable cleaning solution such as Hellmanex cleaning solution. The cleaning process of operation (a) may further include immersing the FTO coated glass in water and/or ethanol after immersing the FTO-coated glass in the cleaning solution. After the immersing(s), the FTO-coated glass may be air dried. The cleaning process of operation (a) may further include subjecting the FTO-coated glass to an ultraviolet-ozone (UV-O₃) treatment. The UV-O₃ treatment may be performed for any suitable period such as from about 1 minute to about 60 minutes, such as from about 10 minutes to about 50 minutes, such as from about 20 minutes to about 40 minutes, such as about 30 minutes.

The deposition process of operation (b) of the substrate-forming process may include dispersing a solution comprising the PEDOT:PSS on the FTO-coated glass. The dispersing forms a thin film of PEDOT:PSS on the FTO-coated glass. A non-limiting example of dispersing is chemical solution deposition. A non-limiting example of chemical solution deposition that may be utilized includes spin coating as described herein. For example, the solution comprising the PEDOT:PSS may form a thin film on a rotating substrate.

The deposition process of operation (b) may include annealing the dispersed solution comprising the PEDOT:PSS, under vacuum, at a first temperature that is from about 95° C. to about 195° C. to form the HTL on the FTO-coated glass. This annealing operation may be performed under vacuum conditions at a first temperature that is from about 95° C. to about 195° C., such as from about 110° C. to about 180° C., such as from about 125° C. to about 165° C., such as from about 135° C. to about 155° C., such as about 145° C.

The deposition process of operation (b) may include heating the first and second layers 201a, 201b at a second temperature that is from about 100° C. to about 200° C., such as from about 115° C. to about 185° C., such as from about 130° C. to about 170° C., such as from about 140° C. to about 160° C., such as about 150° C. to form the substrate 201. The substrate includes a first layer 201a comprising the FTO-coated glass, and a second layer 201b comprising the conductive polymer such as PEDOT:PSS. The second layer 201b includes a first surface adjacent the first layer 201a, and a second surface opposite the first surface, the second surface being the substrate surface to which the precursor solution (comprising the Pb-free double perovskite and the nitrogen-containing compound) is deposited.

Prior to depositing the conductive layer, the solution that includes the conductive polymer may be sonicated or otherwise mixed by suitable methods.

Aspects of the present disclosure also generally relate to compositions that include: a Pb-free double perovskite; and a nitrogen-containing compound or ion thereof. Such compositions may be utilized as a SWIR material. The compositions may be in the form of a film.

The Pb-free double perovskite of compositions described herein may be represented by Formula (I) as described above. Non-limiting examples of the nitrogen-containing compound (or ion thereof) are also described above.

The Pb-free double perovskite of compositions described herein may be represented by Formula (I) (A₂BCX₆) or Formula (II) (Cs₂BCX₆) as described above. Non-limiting examples of the nitrogen-containing compound (or ion thereof) are also described above.

In some aspects, a molar ratio of the Pb-free double perovskite to the nitrogen-containing group or ion thereof in the composition may be from about 0.1:1 to about 0.4:1, such as from about 0.12:1 to about 0.3:1, such as from about 0.14:1 to about 0.22:1, such as about 0.16:1.

Compositions described herein show high stability and high efficiency relative to conventional SWIR compositions. Compositions described herein are also more environmentally friendly relative to conventional SWIR compositions.

The composition may have a highest SWIR absorption at room temperature that is from about 700 nm to about 2800 nm, such as from about 1000 nm to about 2800 nm, such as from about 1000 nm to about 2800 nm, or from about 700 nm to about 1500 nm.

Compositions described herein may be in the form of films. The films may be utilized as a SWIR material. Films described herein may have any suitable thickness. In some aspects, a film described herein has a thickness that is from about 5 nm to about 2,000 nm (about 2 μm), such as from about 10 nm to about 1,750 nm (about 1.75 μm), such as from about 100 nm to about 1000 nm (about 1 μm), such as from about 125 nm to about 900 nm, such as from about 150 to about 800 nm, such as from about 200 nm to about 700 nm, such as from about 250 nm to about 600 nm, such as from about 300 nm to about 500 nm, or from about 150 nm to about 250 nm, such as about 200 nm.

The compositions may be in the form of a film or a thin film and disposed on, e.g., a hole transport layer or other layer.

Aspects described herein may be used in various applications including imaging, sensing, security, and electronic applications such as produce inspection, electronic board inspection, identifying and sorting, surveillance, anti-counterfeiting, process quality control, among others. Aspects described herein may find applications in, for example, automobiles, remote sensing, vehicle control, automated inspection, identifying and sorting, surveillance, anti-counterfeiting, and environmental chemical analysis, among other applications.

The following examples are put forth so as to provide those of ordinary skill in the art with a complete disclosure and description of how to make and use aspects of the present disclosure, and are not intended to limit the scope of aspects of the present disclosure. Efforts have been made to ensure accuracy with respect to numbers used (for example, amounts, dimensions, etc.) but some experimental errors and deviations should be accounted for.

### EXAMPLES

Examples of compositions and devices (e.g., photodetectors) described herein were formed using various materials set out in the Materials and are described further below.

### Materials

Cesium bromide (CsBr, 99%), silver bromide (AgBr, 99.5%), and anhydrous dimethylsulfoxide (DMSO) were purchased from Alfa Aesar. Bismuth (III) tribromide (BiBr₃), hydrazine (NH₂NH₂), hydroiodic acid (HI, 55-58% wt/wt aq. sol.), gamma-butyrolactone (GBL), and Hellmanex III solution were purchased from Sigma-Aldrich. All chemicals were used as received without further purification.

### Example 1: Hydrazinium Iodide Preparation

Hydrazinium iodide (NH₂NH₃I, also referred to as HAI) was used as a non-limiting example of a nitrogen-containing compound. HAI was prepared by mixing hydrazine and hydroiodic acid at a temperature of about 0° C. The hydrazine solution diluted with ethanol (50%) was added into the hydroiodic acid solution slowly until a precipitate formed. The precipitate was recrystallized from cooled ethanol to yield NH₂NH₃I (HAI) as a snow-white powder.

### Example 2: SWIR Device Fabrication

A SWIR device was fabricated using the following general operations: (1) preparation of precursor solution, (2) preparation of fluorine-doped tin oxide (FTO)-coated glass for poly(3,4-ethylenedioxythiophene) polystyrene sulfonate (PEDOT:PSS) coating; (3) PEDOT:PSS coating process; and (4) sample coating process.

### (1) Preparation of Precursor Solution

Prior to formation of the thin film containing the perovskite, the sample (in the form of a precursor solution 202) was prepared in a 2:1:1 ratio (CsBr:AgBr:BiBr₃) using 1.2 M CsBr, 0.6 M AgBr, and 0.6 M BiBr₃ in 9:1 DMSO:GBL as the solvent. A molar ratio of the CsBr to HAI was from 10:1 to 2:1. The precursor solution 202 was then stirred and heated at 75° C. until the solids dissolved.

### (2) Preparation of FTO-Coated Glass for PEDOT:PSS Coating and (3) PEDOT:PSS Coating Process

PEDOT:PSS, a conductive polymer, was utilized as a hole transport layer (HTL). FIG. 1 is a schematic of a device fabrication process 100 to form the example device 204. The example device 204 is an example of a photodetector configuration. The example device 204 includes a substrate 201 that includes a first layer 201a (e.g., FTO-coated glass) and a second layer 201b (an HTL). The HTL includes PEDOT:PSS. The example device 204 further includes a double perovskite-containing layer 205 disposed over the HTL (e.g., the second layer 201b). The double perovskite-containing layer 205 may be a composition, such as a thin film, that includes a Pb-free double perovskite and a nitrogen-containing compound. In this example, the Pb-free double perovskite includes Cs₂AgBiBr₆ and the nitrogen-containing compound includes HAI.

FTO-coated glass, having a center cell width of 50 μm, was cleaned using Hellmanex cleaning solution followed by water and ethanol. The FTO-coated glass was then dried under air stream and subjected to UV-ozone (UV-O₃) treatment for 30 minutes in an Ossila UV-ozone cleaner to provide the cleaned FTO-coated glass.

A PEDOT:PSS solution (Baytron PVP AI 4083) was sonicated in a glass vial 200. After sonication, the cleaned patterned FTO-coated glass was spin coated (operation 110) with 150 μL of PEDOT:PSS at 3500 revolutions per minute (rpm) with 3,500 rad/s² clockwise acceleration for 30 seconds, as shown in FIG. 1. The PEDOT:PSS/FTO-coated glass was transferred to a vacuum oven, where it was annealed (operation 120a) at 145° C. for 30 minutes under vacuum followed by heating (operation 130) at 150° C. for 20 minutes under vacuum to form the substrate 201.

### (4) Sample Coating Process

Quickly after forming the PEDOT:PSS/FTO-coated glass (substrate 201), 150 μL of the precursor solution was deposited on the PEDOT:PSS and spin coated (operation 140) at 2,000 rpm with 500 rad/s² clockwise acceleration for 50 seconds at room temperature. Immediately after the spin coating, it was placed in a vacuum oven to anneal (operation 150) at 170° C. for 30 minutes under vacuum (e.g., less than 500 milliTorr) after which a thin film of the double perovskite-containing composition (in the form of the double perovskite-containing layer 205) was formed, and then allowed to cool (operation 160) to room temperature under vacuum to form the example device 204.

### Responsivity Measurements

For SWIR photodetector performance, a Keithley 2401 source meter was used to apply bias voltages and record currents. A LPSC-1310-FC, Thorlabs, USA light source was used to produce the 1310 nm laser with a tunable output by a neutral density filter which had a spot size of 0.076 cm². All SWIR response characterization was conducted in a dehumidified dark chamber to decrease environmental disturbance. The noise current was extracted from the dark current recorded by the source meter and applied a Fourier transform. The light intensity was measured with a Newport 1916-R Optical Power Meter.

### Non-Limiting Results

An example of the photodetector configuration (the example device 204), the fabrication of which is shown in FIG. 1, includes FTO-coated glass (e.g., the first layer 201a), an HTL comprising PEDOT:PSS (e.g., the second layer 201b). The example device 204 also includes the composition (in the form of a double perovskite-containing layer 205) comprising the Pb-free double perovskite (Cs₂AgBiBr₆) and the nitrogen-containing compound (HAI). In this example, the HTL has a width of 50 μm and a length (L) of 1 mm.

For measurements, needles contact the FTO-coated glass surface (surface of first layer 201a) and the perovskite-containing layer 205 is illuminated via a laser.

### A. Characterization of the Device

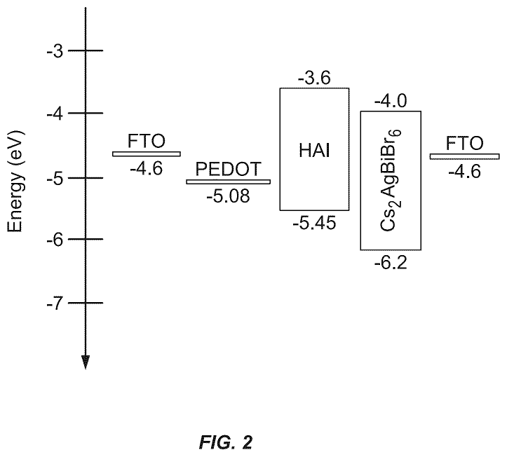

The initial promising nature was solidified through the visualization of an energy diagram with all of the materials in the device. The HTL layer of PEDOT and the incorporation of HAI bridges the Cs₂AgBiBr₆ double perovskite to the FTO, as shown in FIG. 2. It is seen that the conduction band (CB) of Cs₂AgBiBr₆ double perovskite lies at −4.0 eV, and its valence band (VB) at −6.2 eV. Moreover, the CB and VB of HAI are −3.6 and −5.45 eV, respectively, which assists in narrowing the gap of the double perovskite. In addition, PEDOT and the FTO-coated glass fall in this band gap range as well with PEDOT lying at −5.08 eV and FTO at −4.6 eV. Thus, the Cs₂AgBiBr₆ double perovskite is a prime candidate for high responsivity in the SWIR region due to the narrow bandgap in addition to its low cost, nontoxicity, and ease of manufacturing.

### B. Evaluation of Device Performance

The electrical performance of the SWIR device was assessed through responsivity (R) measurements conducted at room temperature under ambient conditions. This value may be derived from the photocurrent relative to the applied voltage under various SWIR illumination intensities. Thus, photoresponsivity, defined as the ratio of photocurrent to incident light power, may be determined by Eq. 1:

$$R = \frac{{I}_{p} - {I}_{d}}{A * P} \qquad ( Eq . 1 )$$

wherein: Iₚ refers to photocurrent under illuminated conditions, I_{d} refers to dark current, A refers to active area of the device, and P refers to incident light intensity.

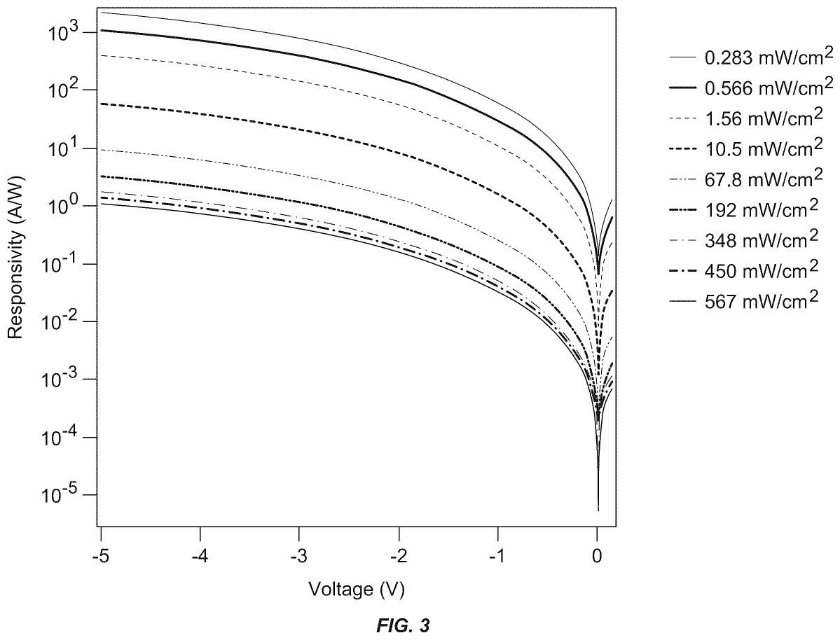

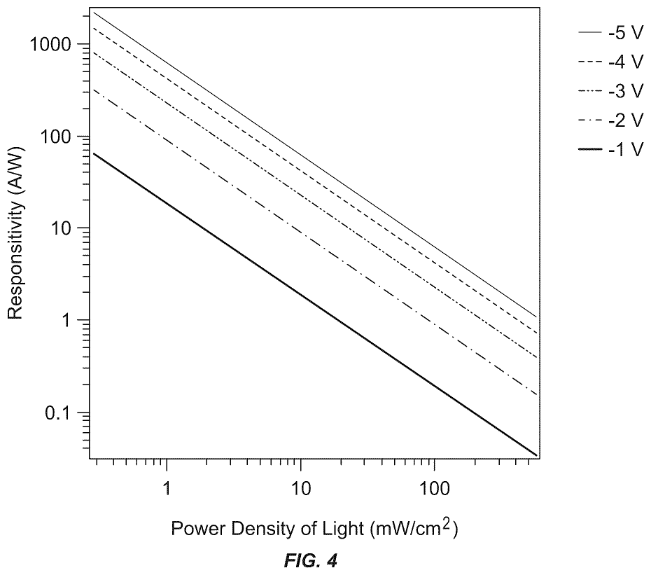

Photoresponsivity is a parameter for evaluating the efficacy of a photodetector. Photoresponsivity represents the ratio of output current to incident light power on the active area of a photodetector. Essentially, photoresponsivity represents the ability of a photodetector to convert incoming light into useful electrical signals. As shown in FIG. 3, a responsivity (R) value of about 2,247 A/W for the SWIR device, was obtained under a low light intensity of 0.283 mW/cm² at 1310 nm with −5.0 V bias. This order of magnitude is substantial and promises a high SWIR efficiency. Furthermore, FIG. 4 depicts photoresponsivity of the SWIR device as a function of light intensity under various biases from −5 V to −1 V. The R values decrease with increased light intensity, primarily due to enhanced recombination of photogenerated carriers.

External quantum efficiency (EQE) is another metric in photodetector technology, illustrating the effectiveness (or efficiency) of the conversion of incoming photons to electrons within a SWIR device. EQE represents the number of free charge carriers generated from the photosensitive material per photon incident upon it. The calculation of EQE provides insight into the performance of a photodetector, particularly in its ability to convert incident light into useful electrical signals. This is vital for its efficient operation in practical applications. EQE may be determined by Eq. 2:

$$EQE = \frac{R * hc}{e λ} \qquad ( Eq . 2 )$$

wherein: R refers to responsivity; h refers to Planck's constant (6.626×10⁻³⁴ J·s), and c refers to speed of light. In the denominator, e refers to elementary charge, or charge of a single electron. The wavelength of the incident light is denoted by λ.

The EQE of the SWIR device was determined to be about 0.898R. Therefore, with a responsivity of about 2,247 A/W achieved under 0.283 mW/cm²-5.0 V bias, the EQE of the SWIR device was determined to be about 2,018 A/W, indicating that the device has excellent properties for use as a photodetector.

Specific detectivity (D*) provides a quantitative measure of the ability of a photodetector to discern weak light signals from inherent noise. That is, it provides a measure of a photodetector's sensitivity and overall performance. Computing D* enables one to understand the performance of the photodetector, especially its capability to discern weak light signals, a factor in its operational efficiency. In addition, this characteristic is important for the device's sensitivity and overall performance. Specific detectivity may be calculated using Eq. 3:

$${D}^{*} = \frac{\sqrt{A Δ f} R}{{i}_{n}} \qquad ( Eq . 3 )$$

wherein: D* refers to specific detectivity; A refers to active area of the device; Δf in units of Hertz (Hz) refers to bandwidth or the range of frequencies over which the device operates; R refers to responsivity (a measure of the device's ability to convert incoming light into electrical signals); and in refers to noise density.

For the SWIR device, calculation of the measured noise density (iₙ) was determined to be about 3.9×10⁻¹¹ at −1 V. The specific detectivity of the SWIR device was determined to be about 8.0×10¹⁰ Jones (cmHz^{1/2}W⁻¹) under −5 V at room temperature in ambient air. Most of the noise is attributed to thermal noise as the measurements are performed at room temperature. Consequently, the specific detectivity determined is excellent for a photodetector with a high associated responsivity.

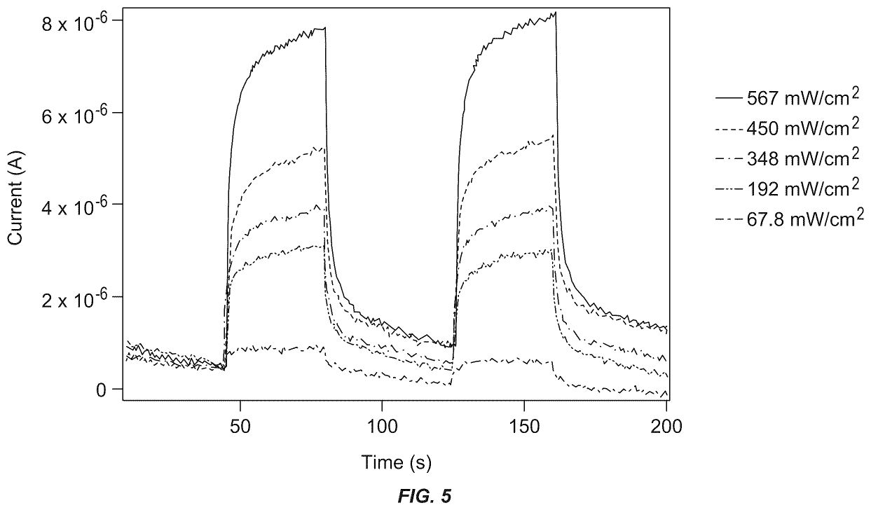

Another parameter of photodetector devices is the response of a device to illumination. The results displayed in FIG. 5 confirms the SWIR photoresponsivity of the SWIR device, showing considerable differences in photocurrent responses with SWIR light on and off at various power intensities. For instance, at room temperature, the SWIR device produced currents of about 8.0×10⁻⁶ A under a −3.0 V bias with a power of 567 mW/cm² at 1310 nm. These characteristics of high responsivity and quick response to SWIR light shows great promise of the SWIR device in SWIR applications.

The theoretical photoconductive gain is a parameter for evaluating the efficacy of a photodetector, representing the ratio of photogenerated charge carriers to absorbed incident photons in the material. A photocurrent of 3.178×10⁻⁴ A was generated under an incident light intensity of 0.283 mW/cm² and a bias of −5 V which was used to determine the photoconductive gain of the SWIR device to be about 1,937. The calculation of theoretical photoconductive gain under different conditions allows the performance of the photodetector to be analyzed for varied potential applications.

Aspects of the present disclosure generally relate to a new class of compositions utilized for detecting short-wave infrared (SWIR) light, to devices including the compositions, and to photodetectors including the compositions. Aspects of the present disclosure also generally relate to processes for forming the compositions, the devices, and the photodetectors. As described, the inventors have found a SWIR detector that may include a Pb-free double perovskite (such as Cs₂AgBiBr₆) and HAI as the nitrogen-containing compound. In some examples, device fabrication includes a sequential spin coating of a PEDOT:PSS solution as the HTL, followed by spin coating of the Pb-free double perovskite-containing precursor solution. The spin coatings may be performed in ambient conditions, and the annealing of the HTL and perovskite-containing layer may be performed at temperatures less than about 175° C. in a standard vacuum oven. As such, devices (e.g., photodetectors) may be made without highly specialized equipment or environmental controls, making them accessible and scalable. Further measurements were performed to calculate the responsivity, specific detectivity, external quantum efficiency (EQE), and gain through a 1310 nm light source focused on the device and a source meter to apply bias and measure the subsequent photocurrent. In some examples, detectors may display an excellent responsivity of about 2,247 A/W may be achieved under 1310 nm light and −5 V bias at room temperature under a light intensity of about 0.283 mW/cm². The detectors may, in some examples, also display an ultra-high EQE of about 2,018 and a gain of about 1,937 under −5 V, exemplifying their strong ability to convert incoming photons to charge carriers supplied to an external circuit. Additionally, and in some examples, detectors may have a specific detectivity of about 8.0×10¹⁰ Jones at room temperature in ambient air, demonstrating the high sensitivity of aspects described herein.

### Aspects Listing

The present disclosure provides, among others, the following aspects, each of which may be considered as optionally including any alternate aspects:

Aspect 1. A process for forming a short-wave infrared device, the process comprising:
forming a precursor solution comprising:
   a first compound (AX) comprising a first monovalent metal cation (A) and a first monovalent anion (X);
   a second compound (BX) comprising a second monovalent metal cation (B) and a second monovalent anion (X), the second monovalent metal cation being different from the first monovalent metal cation;
   a third compound (CX₃) comprising a trivalent metal cation (C) and three third monovalent anions (X), each X being the same or different;
   a nitrogen-containing compound; and
   a solvent;
dispersing the precursor solution on a substrate surface of a substrate;
annealing the dispersed precursor solution on the substrate by heating the substrate at an annealing temperature that is from about 100° C. to about 300° C. to form a film composition comprising:
   the nitrogen-containing compound or ion thereof; and
   a lead-free double perovskite represented by Formula (I):

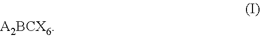

Aspect 2. The process according to aspect 1, wherein the annealing temperature is from about 120° C. to about 220° C.

Aspect 3. The process according to any one of the preceding aspects, wherein the annealing the dispersed precursor solution on the substrate is performed under vacuum.

Aspect 4. The process according to any one of the preceding aspects, wherein the precursor solution comprises: an amount of the first compound (AX) in the solvent is from about 0.2 M to about 2.2 M; a molar ratio of the first compound (AX) to the nitrogen-containing compound is from about 10:1 to about 2:1; a molar ratio of the first compound (AX) to the second compound (BX) is from about 0.5:1 to about 4:1, such as from about 1:1 to about 3:1; a molar ratio of the first compound (AX) to the third compound (CX₃) is from about 0.5:1 to about 4:1, such as from about 1:1 to about 3:1; or combinations thereof.

Aspect 5. The process according to any one of the preceding aspects, wherein the nitrogen-containing compound or ion thereof comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof.

Aspect 6. The process according to any one of the preceding aspects, wherein the solvent of the precursor solution comprises dimethylformamide, dimethylsulfoxide, gamma-butyrolactone, tetrahydrofuran, or combinations thereof.

Aspect 7. The process according to any one of the preceding aspects, wherein the solvent of the precursor solution comprises dimethylsulfoxide and gamma-butyrolactone.

Aspect 8. The process according to aspect 7, wherein the solvent of the precursor solution comprises: a volume ratio of the dimethylsulfoxide to the gamma-butyrolactone that is from about 1:1 to about 17:1.

Aspect 9. The process according to any one of the preceding aspects, wherein, prior to the dispersing the precursor solution on the substrate, the process further comprises: pre-heating the precursor solution at a pre-heating temperature that is from about 40° C. to about 110° C.

Aspect 10. The process according to any one of the preceding aspects, wherein the dispersing the precursor solution on the substrate is performed by spin coating the precursor solution on the substrate.

Aspect 11. The process according to aspect 10, wherein the spin coating the precursor solution comprises: rotating the substrate at 100 rpm to about 4,000 rpm; rotating the substrate at an angular acceleration that is from about 50 rad/s² to about 1,000 rad/s²; rotating the substrate for about 5 minutes or less; or combinations thereof.

Aspect 12. The process according to any one of the preceding aspects, wherein the substrate is formed by a substrate-forming process comprising:
cleaning a fluorine-doped tin oxide-coated glass (FTO-coated glass), comprising:
immersing the FTO-coated glass in a cleaning solution; and then
subjecting the FTO-coated glass to an UV-ozone treatment; and
depositing a conductive layer comprising poly(3,4-ethylenedioxythiophene) polystyrene sulfonate (PEDOT:PSS) on the FTO-coated glass to form the substrate comprising:
   a first layer comprising the FTO-coated glass; and
   a second layer comprising the PEDOT:PSS, the second layer having a first surface adjacent the first layer, and a second surface opposite the first surface, the second surface being the substrate surface.

Aspect 13. The process according to aspect 12, wherein the depositing the conductive layer comprises:
dispersing a solution comprising the PEDOT:PSS on the first layer; then
annealing the dispersed solution comprising the PEDOT:PSS, under vacuum, at a first temperature that is from about 95° C. to about 195° C. to form the second layer on the first layer; and then
heating the first and second layers at a second temperature that is from about 100° C. to about 200° C.

Aspect 14. A process for forming a short-wave infrared device, the process comprising:
forming a precursor solution comprising:
   a first compound (AX) comprising a first monovalent metal cation (A) and a first monovalent anion (X);
   a second compound (BX) comprising a second monovalent metal cation (B) and a second monovalent anion (X), the second monovalent metal cation being different from the first monovalent metal cation;
   a third compound (CX₃) comprising a trivalent metal cation (C) and three third monovalent anions (X), each X being the same or different;
   a nitrogen-containing compound or ion thereof comprising hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof; and
   a solvent comprising dimethylformamide, dimethylsulfoxide, gamma-butyrolactone, tetrahydrofuran, or combinations thereof;
dispersing the precursor solution on a substrate;
annealing the dispersed precursor solution on the substrate by heating the substrate at an annealing temperature that is from about 100° C. to about 300° C. to form a film composition comprising:
   the nitrogen-containing compound or ion thereof; and
   a lead-free double perovskite represented by Formula (I):

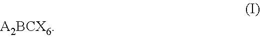

Aspect 15. The process according to aspect 14, wherein: the nitrogen-containing compound or ion thereof comprises hydrazinium ion; and/or the lead-free double perovskite comprises Cs₂AgBiBr₆, Cs₂AgSbBr₆, Cs₂AgInCl₆, Cs₂CuBiBr₆, Cs₂NaBiCl₆, or combinations thereof.

Aspect 16. A short-wave infrared device, comprising:
a hole transport layer; and
a film disposed on the hole transport layer, the film comprising a composition comprising:
   a nitrogen-containing compound or ion thereof; and
   a lead-free double perovskite represented by Formula (I):

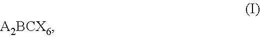

wherein: A of Formula (I) is a first monovalent metal or cation thereof; B of Formula (I) is a second monovalent metal or cation thereof, the second monovalent metal being different from the first monovalent metal; C of Formula (I) is a trivalent metal or cation thereof; and each X of Formula (I) is, independently, a halogen or ion thereof, each X being the same or different.

Aspect 17. The short-wave infrared device according to aspect 16, wherein the composition has a highest SWIR absorption at room temperature that is from about 700 nm to about 1500 nm.

Aspect 18. The short-wave infrared device according to any one of aspects 16 or 17, wherein: A of Formula (I) comprises Cs, Rb, K, Na, Li, or ion thereof. B of Formula (I) comprises Ag, Cu, Au, Na, or ion thereof; C of Formula (I) comprises Bi, Sb, In, or ion thereof; each X of Formula (I) is, independently, Br, Cl, I, or ion thereof; and A and B are different.

Aspect 19. The short-wave infrared device according to any one of aspects 16-18, wherein:
the nitrogen-containing compound or ion thereof comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, a salt thereof, or combinations thereof; and/or
the lead-free double perovskite is represented by Formula (II):

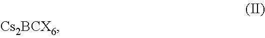

wherein: Cs of Formula (II) is cesium or ion thereof; B of Formula (II) is Ag, Cu, Na, or ion thereof; C of Formula (II) is Bi, Sb, or ion thereof; and each X of Formula (II) is, independently, Cl, Br, or ion thereof, each X of Formula (II) being the same or different.

Aspect 20. The short-wave infrared device according to any one of aspects 16-19, wherein the lead-free double perovskite is selected from the group consisting of Cs₂AgBiBr₆, Cs₂AgSbBr₆, Cs₂AgInCl₆, Cs₂CuBiBr₆, and Cs₂NaBiCl₆.

Where isomers of a named molecule group exist (for example, n-butyl, iso-butyl, sec-butyl, and tert-butyl), reference to one member of the group (for example, n-butyl) shall expressly disclose the remaining isomers (for example, iso-butyl, sec-butyl, and tert-butyl) in the family unless specified to the contrary or the context clearly indicates otherwise. Likewise, reference to a named molecule without specifying a particular isomer (for example, butyl) expressly discloses all isomers (for example, n-butyl, iso-butyl, sec-butyl, and tert-butyl) unless specified to the contrary or the context clearly indicates otherwise. When a compound is described herein such that a particular isomer, enantiomer or diastereomer of the compound is not specified, for example, in a formula or in a chemical name, that description is intended to include each isomer and enantiomer of the compound described individual or in any combination unless specified to the contrary or the context clearly indicates otherwise.

As is apparent from the foregoing general description and the specific aspects, while forms of the aspects have been illustrated and described, various modifications may be made without departing from the spirit and scope of the present disclosure. Accordingly, it is not intended that the present disclosure be limited thereby. Likewise, the term “comprising” is considered synonymous with the term “including.” Likewise whenever a composition, an element, a group of elements, or a method is preceded with the transitional phrase “comprising,” it is understood that we also contemplate the same composition, method, or group of elements with transitional phrases “consisting essentially of,” “consisting of,” “selected from the group of consisting of,” or “Is” preceding the recitation of the composition, element, elements, or method, and vice versa, such as the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. For example, the recitation of the numerical range 1 to 5 includes the subranges 1 to 4, 1.5 to 4.5, 1 to 2, among other subranges. As another example, the recitation of the numerical ranges 1 to 5, such as 2 to 4, includes the subranges 1 to 4 and 2 to 5, among other subranges. Additionally, within a range includes every point or individual value between its end points even though not explicitly recited. For example, the recitation of the numerical range 1 to 5 includes the numbers 1, 1.5, 2, 2.75, 3, 3.80, 4, 5, among other numbers. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “a metal” include aspects comprising one, two, or more metals, unless specified to the contrary or the context clearly indicates only one metal is included.

While the foregoing is directed to aspects of the present disclosure, other and further aspects of the disclosure may be devised without departing from the basic scope thereof, and the scope thereof is determined by the claims that follow.

What is claimed is:

1. A process for forming a short-wave infrared device, the process comprising:
forming a precursor solution comprising:
a first compound (AX) comprising a first monovalent metal cation (A) and a first monovalent anion (X);
a second compound (BX) comprising a second monovalent metal cation (B) and a second monovalent anion (X), the second monovalent metal cation being different from the first monovalent metal cation;
a third compound (CX₃) comprising a trivalent metal cation (C) and three third monovalent anions (X), each X being the same or different;
a nitrogen-containing compound; and
a solvent;
dispersing the precursor solution on a substrate surface of a substrate;
annealing the dispersed precursor solution on the substrate by heating the substrate at an annealing temperature that is from about 100° C. to about 300° C. to form a film composition comprising:
the nitrogen-containing compound or ion thereof; and
a lead-free double perovskite represented by Formula (I):

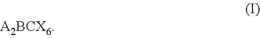

2. The process of claim 1, wherein the annealing temperature is from about 12° C. to about 220° C.

3. The process of claim 1, wherein the annealing the dispersed precursor solution on the substrate is performed under vacuum.

4. The process of claim 1, wherein the precursor solution comprises:
an amount of the first compound (AX) in the solvent is from about 0.2 M to about 2.2 M;
a molar ratio of the first compound (AX) to the nitrogen-containing compound is from about 10:1 to about 2:1;
a molar ratio of the first compound (AX) to the second compound (BX) is from about 0.5:1 to about 4:1;
a molar ratio of the first compound (AX) to the third compound (CX₃) is from about 0.5:1 to about 4:1; or
combinations thereof.

5. The process of claim 1, wherein the nitrogen-containing compound or ion thereof comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof.

6. The process of claim 1, wherein the solvent of the precursor solution comprises dimethylformamide, dimethylsulfoxide, gamma-butyrolactone, tetrahydrofuran, or combinations thereof.

7. The process of claim 1, wherein the solvent of the precursor solution comprises dimethylsulfoxide and gamma-butyrolactone.

8. The process of claim 7, wherein the solvent of the precursor solution comprises:
a volume ratio of the dimethylsulfoxide to the gamma-butyrolactone that is from about 1:1 to about 17:1.

9. The process of claim 1, wherein, prior to the dispersing the precursor solution on the substrate, the process further comprises:
pre-heating the precursor solution at a pre-heating temperature that is from about 40° C. to about 110° C.

10. The process of claim 1, wherein the dispersing the precursor solution on the substrate is performed by spin coating the precursor solution on the substrate.

11. The process of claim 10, wherein the spin coating the precursor solution comprises:
rotating the substrate at 100 rpm to about 4,000 rpm;
rotating the substrate at an angular acceleration that is from about 50 rad/s² to about 1,000 rad/s²;
rotating the substrate for about 5 minutes or less; or
combinations thereof.

12. The process of claim 1, wherein the substrate is formed by a substrate-forming process comprising:
cleaning a fluorine-doped tin oxide-coated glass (FTO-coated glass), comprising:
immersing the FTO-coated glass in a cleaning solution; and then
subjecting the FTO-coated glass to an UV-ozone treatment; and
depositing a conductive layer comprising poly(3,4-ethylenedioxythiophene) polystyrene sulfonate (PEDOT:PSS) on the FTO-coated glass to form the substrate comprising:
a first layer comprising the FTO-coated glass; and
a second layer comprising the PEDOT:PSS, the second layer having a first surface adjacent the first layer, and a second surface opposite the first surface, the second surface being the substrate surface.

13. The process of claim 12, wherein the depositing the conductive layer comprises:
dispersing a solution comprising the PEDOT:PSS on the first layer; then
annealing the dispersed solution comprising the PEDOT:PSS, under vacuum, at a first temperature that is from about 95° C. to about 195° C. to form the second layer on the first layer; and then
heating the first and second layers at a second temperature that is from about 100° C. to about 200° C.

14. A process for forming a short-wave infrared device, the process comprising:
forming a precursor solution comprising:
a first compound (AX) comprising a first monovalent metal cation (A) and a first monovalent anion (X);
a second compound (BX) comprising a second monovalent metal cation (B) and a second monovalent anion (X), the second monovalent metal cation being different from the first monovalent metal cation;
a third compound (CX₃) comprising a trivalent metal cation (C) and three third monovalent anions (X), each X being the same or different;
a nitrogen-containing compound or ion thereof comprising hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof; and
a solvent comprising dimethylformamide, dimethylsulfoxide, gamma-butyrolactone, tetrahydrofuran, or combinations thereof;
dispersing the precursor solution on a substrate;
annealing the dispersed precursor solution on the substrate by heating the substrate at an annealing temperature that is from about 100° C. to about 300° C. to form a film composition comprising:
the nitrogen-containing compound or ion thereof; and
a lead-free double perovskite represented by Formula (I):

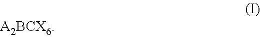

15. The process of claim 14, wherein:
the nitrogen-containing compound or ion thereof comprises hydrazinium ion; and
the lead-free double perovskite comprises Cs₂AgBiBr₆, Cs₂AgSbBr₆, Cs₂AgInCl₆, Cs₂CuBiBr₆, Cs₂NaBiCl₆, or combinations thereof.

16. A short-wave infrared device, comprising:
a hole transport layer; and
a film disposed on the hole transport layer, the film comprising a composition comprising:
a nitrogen-containing compound or ion thereof; and
a lead-free double perovskite represented by Formula (I): 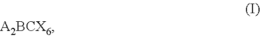
wherein:
A of Formula (I) is a first monovalent metal or cation thereof;
B of Formula (I) is a second monovalent metal or cation thereof, the second monovalent metal being different from the first monovalent metal;
C of Formula (I) is a trivalent metal or cation thereof; and
each X of Formula (I) is, independently, a halogen or ion thereof, each X being the same or different.

17. The short-wave infrared device of claim 16, wherein the composition has a highest SWIR absorption at room temperature that is from about 700 nm to about 1500 nm.

18. The short-wave infrared device of claim 16, wherein:
A of Formula (I) comprises Cs, Rb, K, Na, Li, or ion thereof;
B of Formula (I) comprises Ag, Cu, Au, Na, or ion thereof;
C of Formula (I) comprises Bi, Sb, In, or ion thereof;
each X of Formula (I) is, independently, Br, Cl, I, or ion thereof; and
A and B are different.

19. The short-wave infrared device of claim 16, wherein:
the nitrogen-containing compound or ion thereof comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, a salt thereof, or combinations thereof; and
the lead-free double perovskite is represented by Formula (II): 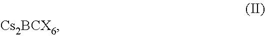
wherein:
Cs of Formula (II) is cesium or ion thereof;
B of Formula (II) is Ag, Cu, Na, or ion thereof;
C of Formula (II) is Bi, Sb, or ion thereof; and
each X of Formula (II) is, independently, Cl, Br, or ion thereof, each X of Formula (II) being the same or different.

20. The short-wave infrared device of claim 19, wherein the lead-free double perovskite is selected from the group consisting of Cs₂AgBiBr₆, Cs₂AgSbBr₆, Cs₂AgInCl₆, Cs₂CuBiBr₆, and Cs₂NaBiCl₆.
